(19) United States
(12) Patent Application Publication
(10) Pub. No.: US 2002/0187566 A1
(43) Pub. Date: Dec. 12, 2002

(54) Method for gettering semiconductor device

(76) Inventor: Il Gweon Kim, Chungcheongbuk-do (KR)

Correspondence Address: JACOBSON HOLMAN PLLC, 400 SEVENTH STREET N.W., SUITE 600, WASHINGTON, DC, 20004, US

(21) Appl. No.: 10/005,608

(22) Filed: Dec. 7, 2001

(30) Foreign Application Priority Data
Jun. 12, 2001 (KR) 2001-32885

(51) Int. Cl. H01L 21/00

(52) U.S. Cl. 438/10

(57) ABSTRACT

A method for gettering a semiconductor device, including steps of growing ingot by an ingot growth method having a pulling speed over 1.5 mm/min and a cooling ratio over 5.0° C./min to form a silicon wafer; and proceeding denudation thermal budget at the silicon wafer, wherein the proceeding denudation thermal budget comprising: forming a trench in the annealed silicon wafer; annealing the trench at about 900 to 1070° C. for about 45 to 90 minutes; filling an HDP oxide film in the trench, and annealing the HDP oxide film at about 900 to 1070° C. for about 45 to 90 minutes; performing a sacrificial oxidation process on the HDP oxide film at about 950 to 1070° C. for about 45 to 90 minutes; and performing a well ion implant process on the annealed silicon wafer, and annealing the resultant wafer at about 950 to 1070° C. for about 45 to 90 minutes.

### BACKGROUND OF THE INVENTION

1. Field of the Invention

The present invention relates to a method for gettering a semiconductor device and, in particular, to an improved method for gettering a semiconductor device which can increase a data retention time of the DRAM, by reducing silicon ingot growth defects according to a fast-pull and fast-cool speed (FPFC) ingot growth method in fabricating a silicon wafer.

2. Description of the Background Art

In general, a gettering process increases a life span of a minority carrier, prevents leakage current in a junction, and reduces influences of charges on an interface of a silicon and an oxide film, by removing impurities and crystals from an active region where a device is formed.

A conventional DRAM performing shallow trench isolation (STI) requires a long data retention time to reduce a standby current. However, when the data retention time of the DRAM is influenced by a tip level energy level induction trap and a great field effect due to a defect of a cell storage NP junction unit, a resultant leakage current level is easily deteriorated by a few tens to a few hundreds bit elements.

In addition, a trench induction mechanical stress and a thermal stress resulting from a high temperature process cause serious dislocation. Accordingly, the DRAM essentially needs to control an STI induction stress generated due to a series of annealing processes for silicon growth defects and denudation.

Especially, to decrease the growth defects on the wafer provides high degree of freedom to reduce the STI induction stress in a denudation process without a trade-off of gettering efficiency.

A hydrogen-annealed wafer is known as an intrinsic getter. On the other hand, in fabricating a semiconductor device, a certain arrangement of the annealing processes may considerably vary a stress resulting from volume expansion strains and thermal mismatch generated due to viscous damping of an oxide film and substitution of the oxide film and a silicon.

It is therefore important to appropriately set up conditions of the STI induction annealing processes. Especially, a high density plasma (HDP) annealing process and a sacrificial oxidation process are major reasons for the STI stress.

A conventional HDP compaction process performed at a temperature over 1150° C. causes serious warpage due to an inappropriate thermal expansion coefficient, thereby increasing overlay resistance in a lithography process.

Moreover, the sacrificial oxidation process changes a stress resulting from viscosity variations of the oxide film and expands the volume.

In a conventional art, a slow-pull and slow-cool method having a pulling speed of 0.5 mm/min and a cooling ratio of 1.0° C./min is employed in a wafer ingot growth process.

However, the conventional method has a disadvantage in that gettering efficiency is reduced after an initial annealing process so as not to completely control initial silicon growth defects. As a result, the data retention time of the DRAM is difficult to control, which is very disadvantageous in a design rule of 0.16 μm.

### SUMMARY OF THE INVENTION

Accordingly, a primary object of the present invention is to provide a method for gettering a semiconductor device which can maximize gettering efficiency by using an ingot growth method increasing an ingot pulling and cooling speed and a denudation thermal budget process in fabricating a silicon wafer.

Another object of the present invention is to provide a method for gettering a semiconductor device which can increase a data retention time of the semiconductor device, by improving a silicon surface defect gettering function to reduce silicon growth defects.

In order to achieve the above-described objects of the present invention, there is provided a method for gettering a semiconductor device, including steps of growing ingot by an ingot growth method having a pulling speed over 1.5 mm/min and a cooling ratio over 5.0° C./min to form a silicon wafer; and proceeding denudation thermal budget at the silicon wafer.

In addition, a method for gettering a semiconductor device according to the present invention includes [the] steps of growing ingot by an ingot growth method having a pulling speed over 1.5 mm/min and a cooling ratio over 5.0° C./min to form a silicon wafer; and proceeding denudation thermal budget at the silicon wafer, wherein the proceeding denudation thermal budget comprising:

annealing the silicon wafer; forming a nitride film on the silicon wafer; forming a trench in the silicon wafer by patterning the nitride film and the silicon wafer; forming a trench side wall oxide film in the trench at about 1000 to 1070° C. for about 50 to 70 minutes; forming an HDP oxide film on the trench side wall oxide film to fill up the trench at about 1000 to 1070° C. for about 50 to 70 minutes; annealing the HDP oxide film at about 1000 to 1070° C. for about 50 to 70 minutes; performing a sacrificial oxidation process on the annealed silicon wafer at about 1000 to 1070° C. for about 50 to 70 minutes; and performing a well implant process and a well annealing process on the silicon wafer.

### BRIEF DESCRIPTION OF THE DRAWINGS

The present invention will become better understood with reference to the accompanying drawings which are given only by way of illustration and thus do not limit the present invention, wherein:

FIG. 1 shows a temperature and process time of a series of annealing processes for denudation determined based on a concept for minimizing a trench induction stress in a method for gettering a semiconductor device in accordance with the present invention;

FIG. 2 is an optical microscope image photograph showing bulk micro defects when simultaneously growing a silicon wafer according to a conventional normal ingot pulling speed and normal cooling ratio method and performing the series of annealing processes determined based on the concept for minimizing the trench induction stress, in the method for gettering the semiconductor device in accordance with the present invention;

FIG. 3 is an optical microscope image photograph showing bulk micro defects when simultaneously growing the silicon wafer according to a fast ingot pulling speed and fast cooling ratio method and performing the series of annealing processes determined based on the concept for minimizing the trench induction stress, in the method for gettering the semiconductor device in accordance with the present invention;

FIGS. 4 to 11 are cross-sectional diagrams illustrating sequential steps of the method for gettering the semiconductor device in accordance with the present invention;

FIG. 12 is a graph showing an oxygen ion density by a radius position of the wafer in a combination of the conventional slow pulling speed and slow cooling ratio and the thermal budget process of the present invention (B) and the fast pulling speed and fast cooling speed and the thermal budget process of the present invention (C);

FIG. 13 is a graph showing a cell leakage current by an HDP compaction annealing temperature in accordance with the present invention;

FIG. 14 is a photograph showing an STI stress distribution by a temperature of a sacrificial oxidation process and a thickness of an oxide film, wherein (a) depicts the sacrificial oxidation temperature is 1050° C. and the thickness of the oxidation film is 100 Å, (b) depicts the sacrificial oxidation temperature is 1050° C. and the thickness of the oxidation film is 300 Å, and (c) depicts the sacrificial oxidation temperature is 800° C. and the thickness of the oxidation film is 100 Å;

FIG. 15 is a graph showing a stress when (a) of FIG. 14 has a different sacrificial oxidation temperature in accordance with the present invention;

FIG. 16 is a graph showing a stress by the sacrificial oxidation thickness in accordance with the present invention;

FIG. 17 is a graph showing an accumulation probability by a storage junction leakage current obtained when a thermal budget process having a varied HDP compaction temperature and sacrificial oxidation temperature is applied to the conventional slow pulling and slow cooling speed (A), when a thermal budget process of the present invention is applied to the conventional method (B), and when the thermal budget process of the present invention is applied to a fast pulling and fast cooling speed of the present invention (C);

FIG. 18 is a graph showing an accumulation probability by a normal refresh obtained when the thermal budget process having a varied HDP compaction temperature and sacrificial oxidation temperature is applied to the conventional slow pulling and slow cooling speed (A), when the thermal budget process of the present invention is applied to the conventional method using SPSC(slow pulling and slow cooling speed) (B), and when the thermal budget process of the present invention is applied to the fast pulling and fast cooling speed of the present invention (C);

FIG. 19 is an enlarged graph of FIG. 18 showing that tail components of a data retention time are improved by 60% and 40%, by reducing the trench stress by using the fast pulling and the fast cooling speed; and

FIG. 20 is a graph showing that an average of Tref 1E-4% is more improved in the present invention (C) than the combination of the conventional method using SPSC(slow pulling and slow cooling speed) and the present invention (B) by 40%.

### DETAILED DESCRIPTION OF THE PREFERRED EMBODIMENTS

A method for gettering a semiconductor device in accordance with a preferred embodiment of the present invention will now be described in detail with reference to the accompanying drawings.

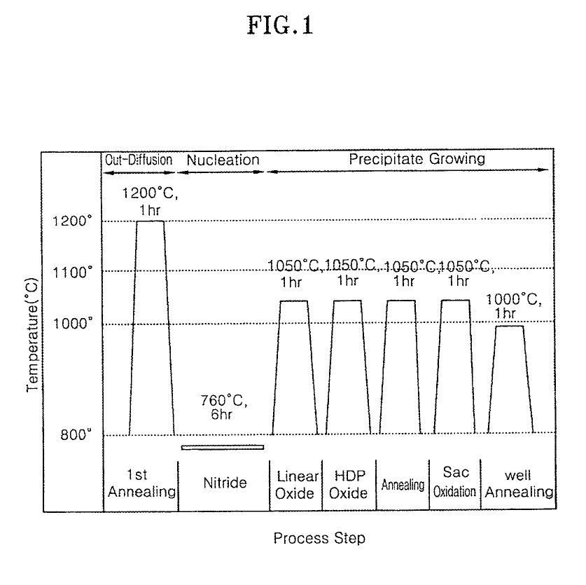

FIG. 1 shows a temperature and process time of a series of annealing processes for denudation determined based on a concept for minimizing a trench induction stress in the method for gettering the semiconductor device in accordance with the present invention.

FIG. 2 is an optical microscope image photograph showing bulk micro defects when simultaneously growing a silicon wafer according to a conventional normal ingot pulling speed and normal cooling ratio method and performing the series of annealing processes determined based on the concept for minimizing the trench induction stress, in the method for gettering the semiconductor device in accordance with the present invention.

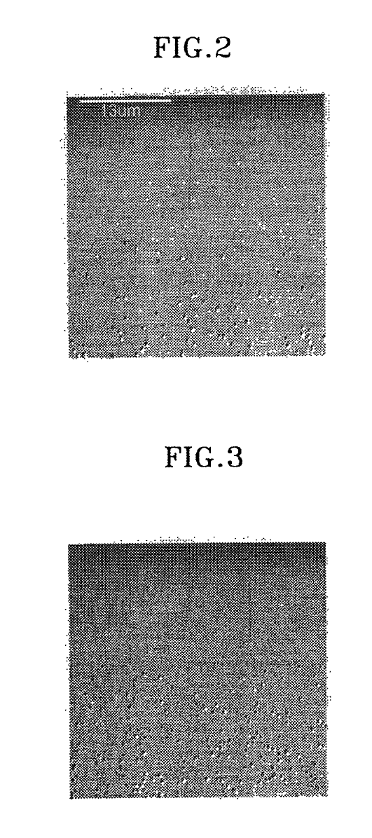

FIG. 3 is an optical microscope image photograph showing bulk micro defects when simultaneously growing the silicon wafer according to a fast ingot pulling speed and fast cooling ratio method and performing the series of annealing processes determined based on the concept for minimizing the trench induction stress, in the method for gettering the semiconductor device in accordance with the present invention.

Referring to FIGS. 2 and 3, when silicon is grown by introducing the fast pulling and fast cooling method of the present invention to the conventional art, a bulk micro defect region is developed. It implies that defects are reduced on a silicon surface layer where a series of processes are actually performed.

As illustrated in FIG. 1, when a denudation thermal budget process is performed on the wafer grown by using the fast pulling speed and the fast cooling speed (FPFC), oxygen in the wafer is diffused out, thus reducing an oxygen density on a surface formation region.

The unstable oxygen grown near the crystal oriented particles of the low oxygen density region is discharged according to a high temperature annealing process.

At this time, an interstitial implanted through the surface of the wafer in a high temperature oxidation process combines with the crystal originated particles reduced in volume by oxygen discharge, to annihilate the particles. Accordingly, the crystal originated particles are almost removed in an element formation region.

A fast pulling wafer has many vacancies according to a three-step annealing process, and thus oxygen precipitates are well formed. Therefore, the bulk micro defects are developed to improve gettering efficiency.

In the case of a conventional normal wafer using normal pulling, the crystal originated particles have a large size, and thus are not completely removed according to the annealing process. In addition, development of the bulk micro defects by vacancies is generated not on the whole surface of the wafer but in the wafer. Accordingly, the conventional wafer has lower gettering efficiency than the wafer produced using fast pulling.

On the other hand, as shown in FIG. 1, the oxygen precipitation of the present invention is dependent upon the denudation process including six annealing processes. An exposure annealing process for high gettering movement is divided into three category annealing processes.

Here, the first annealing process is carried out at about 1200° C. in an oxygen atmosphere, and the second annealing process is performed at about 760° C. for nucleation. In the third annealing process, the oxygen precipitation growth is generated at a high temperature through a few consecutive annealing processes.

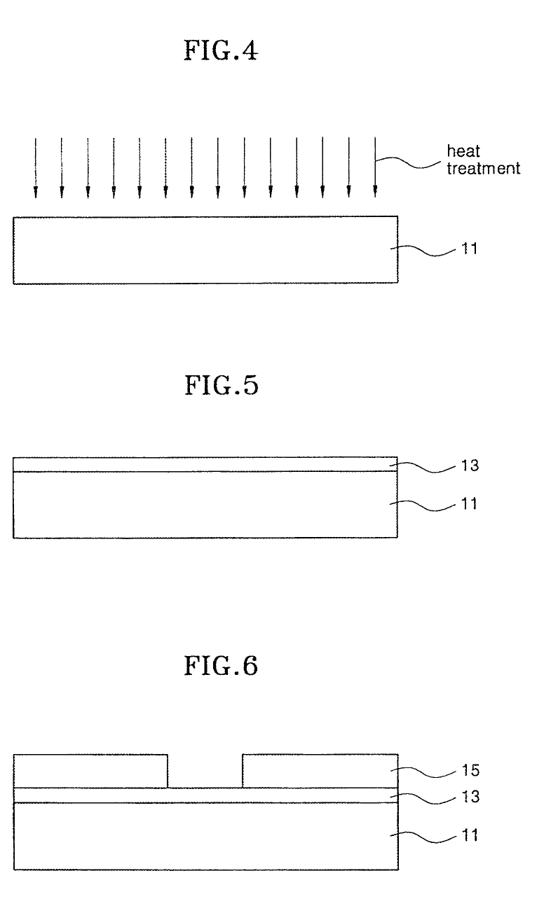

The method for gettering the semiconductor device in accordance with the present invention will now be described with reference to FIGS. 4 to 11.

FIGS. 4 to 11 are cross-sectional diagrams illustrating sequential steps of the method for gettering the semiconductor device in accordance with the present invention.

Firstly, silicon is grown on a silicon wafer according to an ingot growth method having a pulling speed over 1.5 mm/min and a cooling ratio over 5.0° C./min. More preferably, the silicon is grown according to the ingot growth method having a pulling speed over 1.8 mm/min and a cooling ratio over 9.0° C./min.

As depicted in FIG. 4, the thermal budget process is performed on the silicon wafer 11 a few times at about 1100 to 1250° C. for about 45 to 90 minutes. Preferably, the annealing process is performed thereon at about 1150 to 1230° C. for about 50 to 70 minutes. More preferably, the annealing process is performed at about 1200° C. for about an hour.

Then, as shown in FIG. 5, an Si₃N₄ film 13 is deposited on the silicon wafer 11 at a low temperature. Here, the Si₃N₄ film 13 is deposited thereon at about 700 to 800° C. for about 5 to 7 hours. Preferably, the Si₃N₄ film 13 is deposited thereon at about 730 to 780° C. for about 5 hours and 30 minutes to 6 hours and 30 minutes. More preferably, the Si₃N₄ film 13 is deposited thereon at about 740 to 780° C. for about 5 hours and 40 minutes to 6 hours and 10 minutes.

As illustrated in FIG. 6, a photoresist film 15 is coated on the Si₃N₄ film 13, and then selectively patterned according to exposure and development processes employing photolithography, thereby forming a photoresist film pattern 15 for a trench mask. Thereafter, the Si₃N₄ film 13 is selectively patterned by using the photoresist film pattern 15 as a mask, to expose the silicon wafer 11.

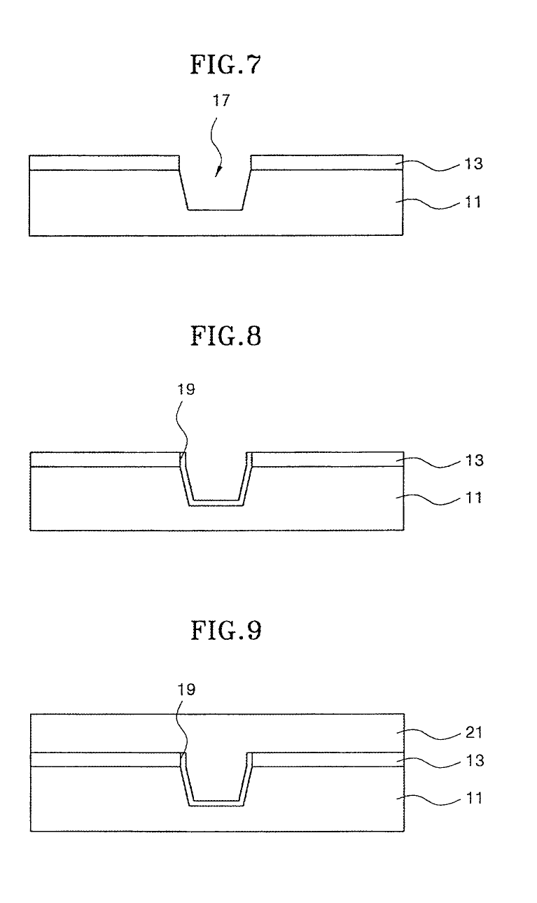

Referring to FIG. 7, the silicon wafer 11 is selectively patterned by using the photoresist film pattern 15 and the selectively-patterned Si₃N₄ film 13 as a mask, thereby forming a trench 17. Here, the trench 17 defines an active region pattern at a field depth of about 3500 Å.

As shown in FIG. 8, the photoresist film pattern 15 is removed, and a linear oxide film 19 is formed in the trench 17 according to a high temperature annealing process. Here, the annealing process is performed at about 950 to 1090° C. for about 45 minutes to one and half hours. Preferably, the annealing process is performed at about 1000 to 1070° C. for about 50 to 70 minutes. More preferably, the annealing process is performed at about 1040 to 1060° C. for about 55 to 65 minutes.

As depicted in FIG. 9, an HDP oxide film 21 filling up the trench 17 is formed over the resultant structure including the trench 17. At this time, the HDP oxide film 21 is deposited at about 950 to 1090° C. for about one hour. Preferably, the HDP oxide film 21 is deposited at about 1000 to 1070° C. for about 50 to 70 minutes. More preferably, the HDP oxide film 21 is deposited at about 1040 to 1060° C. for about 55 to 65 minutes.

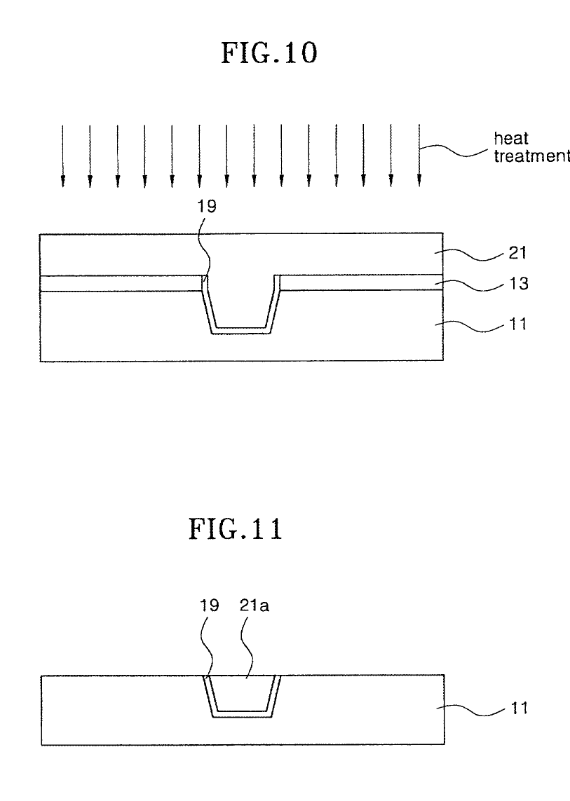

Referring to FIG. 10, a high temperature annealing process is performed on the HDP oxide film 21 for compaction before a chemical mechanical polishing (CMP) process. Here, the annealing process is performed at about 950 to 1100° C. for about one hour. Preferably, the annealing process is performed at about 1000 to 1070° C. for about 50 to 70 minutes. More preferably, the annealing process is performed at about 1040 to 1060° C. for about 55 to 65 minutes.

Thereafter, the HDP oxide film 21 and the Si₃N₄ film 13 are selectively removed according to the CMP process, to form an element isolating film 21a, shown in FIG. 11.

Although not illustrated, a sacrificial oxidation process is performed on the CMP-processed silicon wafer 11. Here, the sacrificial oxidation process is performed at about 950 to 1090° C. for about one hour. In addition, an oxide film (not shown) is deposited at a thickness of about 50 to 150 Å according to the sacrificial oxidation process. Preferably, the oxide film is deposited at a thickness of about 100 Å.

Preferably, the sacrificial oxidation process is performed at about 1000 to 1070° C. for about 50 to 70 minutes. More preferably, the sacrificial oxidation process is performed at about 1040 to 1060° C. for about 55 to 65 minutes.

Although not illustrated, a well implant process and a high temperature well annealing process are sequentially performed. At this time, the high temperature well annealing process is performed at about 900 to 1040° C. for about 25 to 80 minutes. Preferably, the high temperature well annealing process is performed at about 950 to 1030° C. for about 30 to 65 minutes. More preferably, the high temperature well annealing process is performed at about 990 to 1010° C. for about 35 to 55 minutes.

The results of the aforementioned processes will now be explained in more detail.

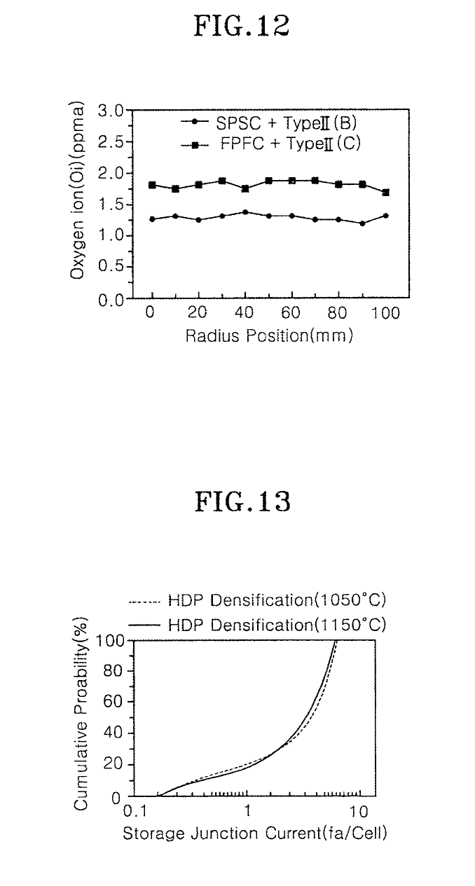

FIG. 12 is a graph showing an oxygen ion density by a radius position of the wafer in a combination of the conventional method and the present invention (B) and the present invention (C). According to the radius position of the wafer, the oxygen density of (C) is higher than that of (B).

As described above, a certain arrangement of the annealing processes may considerably vary a stress resulting from volume expansion strains and thermal mismatch generated due to viscous damping of the oxide film and substitution of the oxide film and the silicon in the oxidation process. It is therefore important to appropriately set up the arrangement to form a sufficient denuded zone without causing STI induction. Especially, the HDP compaction annealing process and the sacrificial oxidation process may be main sources of the STI stress.

The HDP compaction process performed at a temperature over 1150° C. generates serious warpage due to an inappropriate thermal expansion coefficient, thereby increasing overlay resistance in a lithography process. Moreover, the sacrificial oxidation process changes a stress resulting from viscosity variations of the oxide film and expands the volume.

According to the present invention, the HDP compaction annealing process and the sacrificial oxidation process are preferably performed at a temperature of about 1050° C.

Although not illustrated, a leakage source may exist in a depletion layer in a full charge state in view of an interaction between defects and STI deformation. In the case of the silicon grown by the conventional method, curvature is generated in the wafer due to the HDP compaction annealing temperature. That is, when the annealing process is performed at 1150° C., a slip band may be generated in the wafer. As shown in FIG. 13, the slip band phenomenon is removed at 1050° C. from the edges of the wafer.

When the HDP compaction temperature is increased, the wafer is twisted due to thermal deformation in spite of high gettering efficiency. However, as depicted in FIG. 13, the thermal deformation is compensated by the increased oxidation viscosity and gettering efficiency, and thus cell leakage is not much influenced.

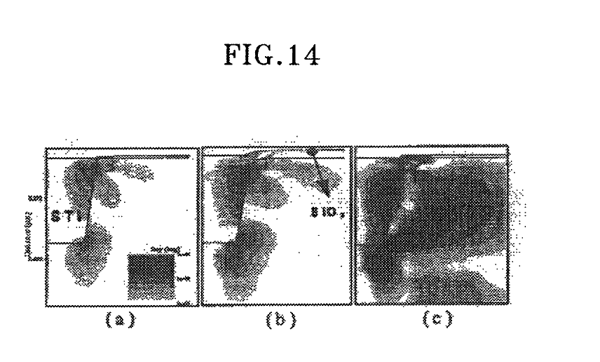

FIG. 14 is a photograph showing an STI stress distribution by a temperature of a sacrificial oxidation process and a thickness of an oxide film, wherein (a) the sacrificial oxidation temperature is about 1050° C. and the thickness of the oxidation film is 100 Å, (b) the sacrificial oxidation temperature is about 1050° C. and the thickness of the oxidation film is 300 Å, and (c) the sacrificial oxidation temperature is 800° C. and the thickness of the oxidation film is 100 Å.

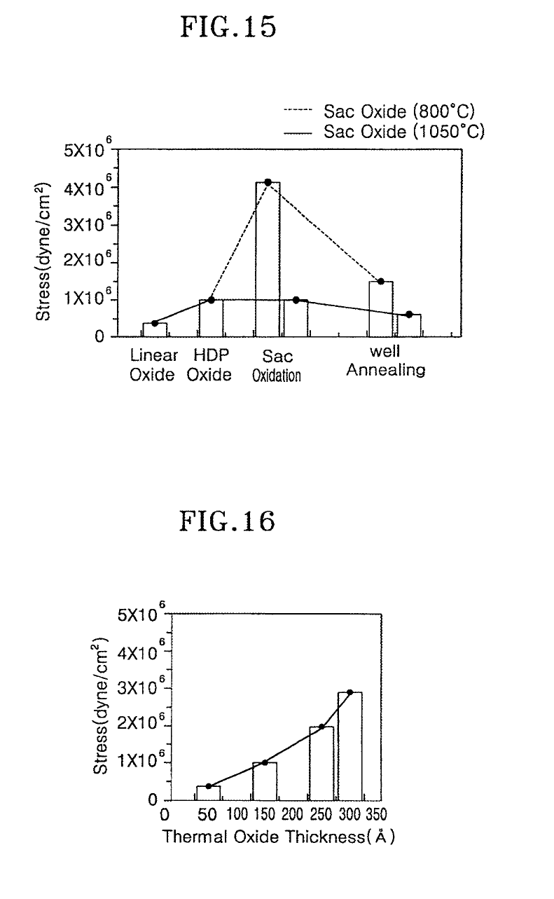

FIG. 15 is a graph showing a stress when (a) of FIG. 14 has a different sacrificial oxidation temperature in accordance with the present invention.

FIG. 16 is a graph showing a stress by the sacrificial oxidation thickness in accordance with the present invention. Referring to FIG. 14, when the sacrificial oxidation temperature is low and the sacrificial oxide film is thick, the stress is increased in peripheral regions including the trench. Accordingly, the sacrificial oxidation process is very important in generation of the STI stress. As shown in FIGS. 15 and 16, the high temperature and the small thermal oxidation are efficient to reduce the STI-deformation.

Although not illustrated, an SEM image of an STI potential near an adjacent gate region is observed after a light etch process to verify the simulation result. When the STI potential exists at 800° C., deformation is increased due to expansion of SiO₂, and SiO₂ is observed due to reduced oxidation viscosity.

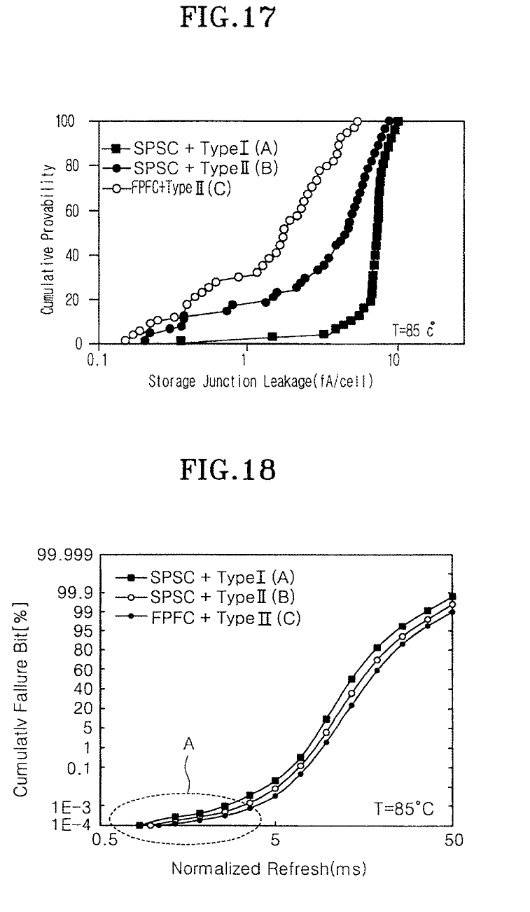

On the other hand, referring to the comparison result of an accumulation probability by the cell leakage in FIG. 17, the present invention (C) is superior in the cell leakage to the conventional method using the thermal budget process having a varied HDP compaction temperature of f 1150° C. and sacrificial oxidation temperature of 800° C. is applied to the conventional slow pulling speed of 0.5 mm/min and slow cooling speed of 1.0° C./min (A; SPSC+Type I) and the combination of the conventional method using slow pulling speed of 0.5 mm/min and slow cooling speed of 1.0° C./min and the present invention having HDP temperature of about 1050° C. and sacrificial oxidation temperature of about 1050C (B; SPSC+Type II) due to the decreased growth defects and STI-deformation.

FIG. 18 is a graph showing an accumulation probability by a normal refresh obtained when the thermal budget process having a varied HDP compaction temperature of f 1150° C. and sacrificial oxidation temperature of 800° C. is applied to the conventional slow pulling speed of 0.5 mm/min and slow cooling speed of 1.0° C./min (A; SPSC +Type I), when the thermal budget process having HDP temperature of about 1050° C. and sacrificial oxidation temperature of about 1050° C. of the present invention is applied to the conventional slow pulling speed of 0.5 mm/min and slow cooling speed of 1.0° C./min (B; SPSC+Type II), and when the thermal budget process having HDP temperature of about 1050° C. and sacrificial oxidation temperature of about 1050° C. of the present invention is applied to the fast pulling and fast cooling speed of the present invention (C; FPFC+Type II).

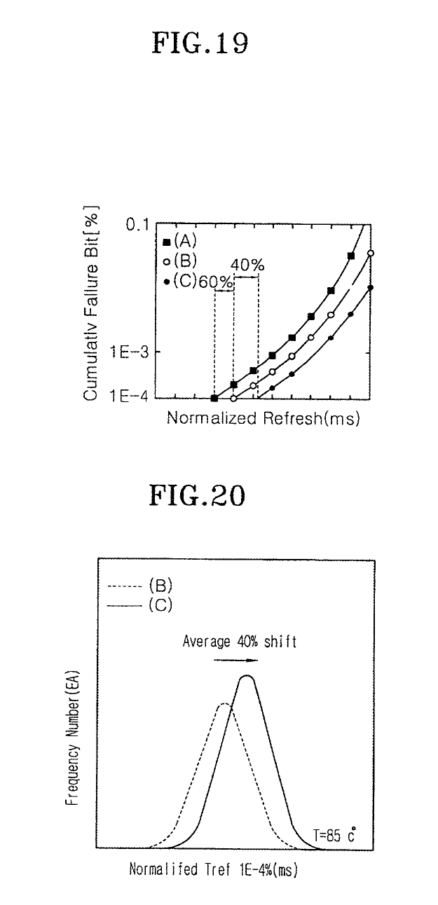

FIG. 19 is an enlarged graph of FIG. 18 showing that tail components of a data retention time are improved by 60% and 40%, by reducing the trench stress by using the fast pulling and the fast cooling speed.

FIG. 20 is a graph showing that an average of Tref 1E-4% is more improved in the present invention (C) than the combination of the conventional method and the present invention (B) by 40%.

As depicted in FIGS. 18 to 20, when the present invention (C) is compared with the conventional method (A) and the combination of the conventional method and the present invention (B), the tail components of the data retention time of (B) show an improvement of 60% over that of (A), and the tail components of the data retention time of (C) show a 40% improvement over that of (B) due to reduction of the STI-deformation.

Accordingly, the data retention time can be improved without increasing the STI-deformation and reducing the gettering efficiency.

The method for gettering the semiconductor device in accordance with the present invention has the following advantages:

When the wafer is grown by using the fast pulling and fast cooling speed and the series of denudation thermal budge processes are appropriately set up, the data retention time of the DRAM is remarkably increased.

In addition, the tail components of the data retention time are improved by 60% by reducing the STI induction stress.

Moreover, the tail components of the data retention time are improved by 40% according to the high efficiency denudation process using the FPFC method.

A unit cost of the wafer is considerably reduced by increasing the ingot pulling speed and the cooling ratio. Thus, the wafer of the present invention is more advantageous in cost than the conventional hydrogen-annealed wafer.

Furthermore, the absolute gettering efficiency is increased to reduce the wafer warpage generated due to the high temperature process at the time of setting up a temperature of the denudation thermal budget process.

As the present invention may be embodied in several forms without departing from the spirit or essential characteristics thereof, it should also be understood that the above-described embodiment is not limited by any of the details of the foregoing description, unless otherwise specified, but rather should be construed broadly within its spirit and scope as defined in the appended claims, and therefore all changes and modifications that fall within the metes and bounds of the claims, or equivalences of such metes and bounds are therefore intended to be embraced by the appended claims.

What is claimed is:

1. A method for gettering a semiconductor device, comprising steps of:
growing ingot by an ingot growth method having a pulling speed over 1.5 mm/min and a cooling ratio over 5.0° C./min to form a silicon wafer; and
proceeding denudation thermal budget at the silicon wafer.

2. The method according to claim 1, wherein the proceeding denudation thermal budget comprising:
forming a trench in the silicon wafer;
annealing the trench at about 900 to 1070° C. for about 45 to 90 minutes;
filling an HDP oxide film in the trench, and annealing the HDP oxide film at about 900 to 1070° C. for about 45 to 90 minutes;
performing a sacrificial oxidation process on the HDP oxide film at about 950 to 1070° C. for about 45 to 90 minutes; and
performing a well ion implant process on the annealed silicon wafer, and annealing the resultant wafer at about 950 to 1070° C. for about 45 to 90 minutes.

3. The method according to claim 1, further comprises a step for annealing the silicon wafer at about 1150 to 1250° C. for about 50 to 70 minutes.

4. The method according to claim 2, further comprising a step for forming a nitride film at about 730 to 780° C. for about 5 to 7 hours after annealing the silicon wafer.

5. The method according to claim 2, wherein the trench is annealed at about 1000 to 1070° C. for about 50 to 70 minutes.

6. The method according to claim 2, wherein the HDP oxide film is annealed at about 1000 to 1070° C. for about 50 to 70 minutes.

7. The method according to claim 2, wherein the sacrificial oxidation process is performed at about 1000 to 1070° C. for about one hour.

8. The method according to claim 2, further comprising a step for performing a well ion implant process and a well annealing process after the sacrificial oxidation process.

9. The method according to claim 2, wherein a sacrificial oxide film is formed at a thickness of about 50 to 150 Å in the sacrificial oxidation process.

10. The method according to claim 8, wherein the well annealing process is performed at about 950 to 1040° C. for about 30 to 70 minutes.

11. The method according to claim 2, wherein the step for growing silicon is performed according to an ingot growth method having a pulling speed over 1.8 mm/min and a cooling ratio over 9.0° C./min.

12. A method for gettering a semiconductor device, comprising steps of:
growing ingot by an ingot growth method having a pulling speed over 1.5 mm/min and a cooling ratio over 5.0° C./min to form a silicon wafer; and
proceeding denudation thermal budget at the silicon wafer,
wherein the proceeding denudation thermal budget comprising:
annealing the silicon wafer;
forming a nitride film on the silicon wafer;
forming a trench in the silicon wafer by patterning the nitride film and the silicon wafer;
forming a trench side wall oxide film in the trench at about 1000 to 1070° C. for about 50 to 70 minutes;
forming an HDP oxide film on the trench side wall oxide film to fill up the trench at about 1000 to 1070° C. for about 50 to 70 minutes;
annealing the HDP oxide film at about 1000 to 1070° C. for about 50 to 70 minutes;
performing a sacrificial oxidation process on the annealed silicon wafer at about 1000 to 1070° C. for about 50 to 70 minutes; and
performing a well implant process and a well annealing process on the silicon wafer.

13. The method according to claim 12, wherein the silicon wafer is annealed at about 1150 to 1250° C. for about 50 to 70 minutes.

14. The method according to claim 12, wherein the trench is annealed at about 1000 to 1070° C. for about 50 to 70 minutes.

15. The method according to claim 12, wherein the HDP oxide film is annealed at about 1000 to 1070° C. for about 50 to 70 minutes.

16. The method according to claim 12, wherein a sacrificial oxide film is formed at a thickness of about 50 to 150 Å in the sacrificial oxidation process.

17. The method according to claim 12, wherein the well annealing process is performed at about 950 to 1040° C. for about 30 to 70 minutes.

18. The method according to claim 12, wherein the step for growing silicon is performed according to an ingot growth method having a pulling speed over 1.8 mm/min and a cooling ratio over 9.0° C./min.
